(19) United States
(12) Patent Application Publication
(10) Pub. No.: US 2026/0239948 A1
(43) Pub. Date: Aug. 13, 2026

(54) METAL HALIDE PRE-SOAK AND PLASMA TREATMENT PROCESS SEQUENCE

(71) Applicant: Applied Materials, Inc., Santa Clara, CA (US)

(72) Inventors: Joung Joo LEE, San Jose, CA (US); Yang HU, Santa Clara, CA (US); Avgerinos V. GELATOS, Scotts Valley, CA (US); Gaurav THAREJA, Santa Clara, CA (US); Chi Hong CHING, Santa Clara, CA (US)

(21) Appl. No.: 19/281,433

(22) Filed: Jul. 25, 2025

Related U.S. Application Data
(60) Provisional application No. 63/758,274, filed on Feb. 13, 2025.

(51) Int. Cl. H01L 21/768

(52) U.S. Cl. CPC H10W 20/096; H10W 20/056

(57) ABSTRACT

Embodiments of the disclosure include a method of forming an interconnect structure that is coupled to a metal gate of a field effect transistor (FET). The method includes exposing a device structure to a metal halide pre-soak, wherein the device structure comprises at least one feature formed in a first dielectric layer, wherein the at least one feature exposes a surface of a second dielectric layer surrounding a metal gate. The method further includes exposing the device structure to a plasma treatment, and at least partially filling the at least one feature with a metal fill material.

### CROSS-REFERENCE TO RELATED APPLICATIONS

This application claims benefit of U.S. provisional patent application Ser. No. 63/758,274, filed Feb. 13, 2025, which is herein incorporated by reference.

### BACKGROUND

### Field

Embodiments of the present disclosure generally relate to a semiconductor device and methods of forming a semiconductor device. More particularly, the disclosure relates to a device and methods of forming an interconnect structure that is coupled to a metal gate of a field effect transistor (FET).

### Description of the Related Art

The fabrication of microelectronic devices typically involves a complicated process sequence requiring hundreds of individual processes performed on semi-conductive, dielectric and conductive substrates. Examples of these processes include oxidation, diffusion, ion implantation, thin film deposition, cleaning, etching, lithography among other operations. Each operation is time consuming and expensive.

With ever-increasing critical dimensions for the microelectronic devices, the design and fabrication for these devices on substrates becomes increasingly complex. Control of the critical dimensions and process uniformity becomes increasingly more significant. Complex multilayer stacks involve precise process monitoring of critical process related variables such as thickness, roughness, stress, density, and potential defects. However, each process recipe used to form the multilayer stack may utilize one or more processing chambers which adds additional time to form the devices in the processing systems and also provides additional opportunities for forming defects. Thus, each process adds to the overall fabrication cost for the completed microelectronic devices.

Additionally, as critical dimensions on devices shrink and high aspect ratio features become more common, it has become increasingly difficult to reliably pattern and fill high aspect ratio features using current fabrication techniques.

As devices shrink and layer thicknesses shrink, it has also become increasingly difficult to selectively remove a portion of a first layer disposed over an underlying layer in a high aspect ratio feature without damaging a portion of the underlying layer. In one example, processes used to selectively etch dielectric layers formed over a metal gate structure, to allow an interconnect to be formed to a portion of the metal gate, have become increasingly difficult.

Therefore, there is a need for improved fabrication methods that solves the problems described above.

### SUMMARY

The present disclosure generally relates to a semiconductor device and methods of forming a semiconductor device. More particularly, the disclosure relates to a device and methods of forming an interconnect structure that is coupled to a metal gate of a field effect transistor (FET).

Embodiments of the disclosure include a method of forming an interconnect within a device structure. The method includes exposing a device structure to a metal halide pre-soak, wherein the device structure comprises at least one feature formed in a first dielectric layer, wherein the at least one feature exposes a surface of a second dielectric layer surrounding a metal gate. The method further includes exposing the device structure to a plasma treatment, and at least partially filling the at least one feature with a metal fill material.

Embodiments of the disclosure further include a method of forming an interconnect within a device structure. The method includes exposing a first dielectric layer of a device structure to a plasma treatment process, wherein the device structure has at least one feature formed therein, and wherein the at least one feature comprises a bottom surface and sidewalls, the first dielectric layer disposed at the bottom surface, and a second dielectric layer forming at least a portion of the sidewalls. The plasma treatment process further including exposing the device structure to a plasma comprising hydrogen-containing precursors.

Embodiments of the disclosure also include a method of forming an interconnect within a device structure. The method includes exposing a device structure to a metal halide pre-soak, the metal halide pre-soak comprising exposing the device structure to titanium tetrachloride (TiCl4) from about 3 minutes to about 6 minutes at a temperature from about 200 degrees Celsius to about 500 degrees Celsius. The device structure comprising a bottom surface and sidewalls and at least one feature formed in a first dielectric layer, wherein the at least one feature exposes a surface of a second dielectric layer surrounding a metal gate. The method further includes the first dielectric layer disposed at the bottom surface, wherein the first dielectric comprises hafnium oxide and the second dielectric layer forming at least a portion of the sidewalls. And exposing the device structure to a plasma treatment process, the plasma treatment process comprising exposing the device structure to a plasma comprising hydrogen-containing precursors and at least partially filling the at least one feature with a metal fill material.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments of the disclosure and are therefore not to be considered limiting of its scope, as the disclosure may admit to other equally effective embodiments.

FIG. 1 illustrates a schematic top view of one example of a multi-chamber processing tool in accordance with one or more embodiments described herein.

FIG. 2 illustrates a process flow diagram for a method of forming an interconnect structure, according to one or more embodiments of the present disclosure.

FIGS. 3A, 3B, 3C, 3D, and 3E illustrate view of various stages of forming an interconnect structure, according to one or more embodiments of the present disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the disclosure generally relate to a semiconductor device and methods of forming a semiconductor device. More particularly, the disclosure relates to methods of forming an interconnect structure coupled to an isolated metal gate structure.

### Example Multi-chamber Processing System

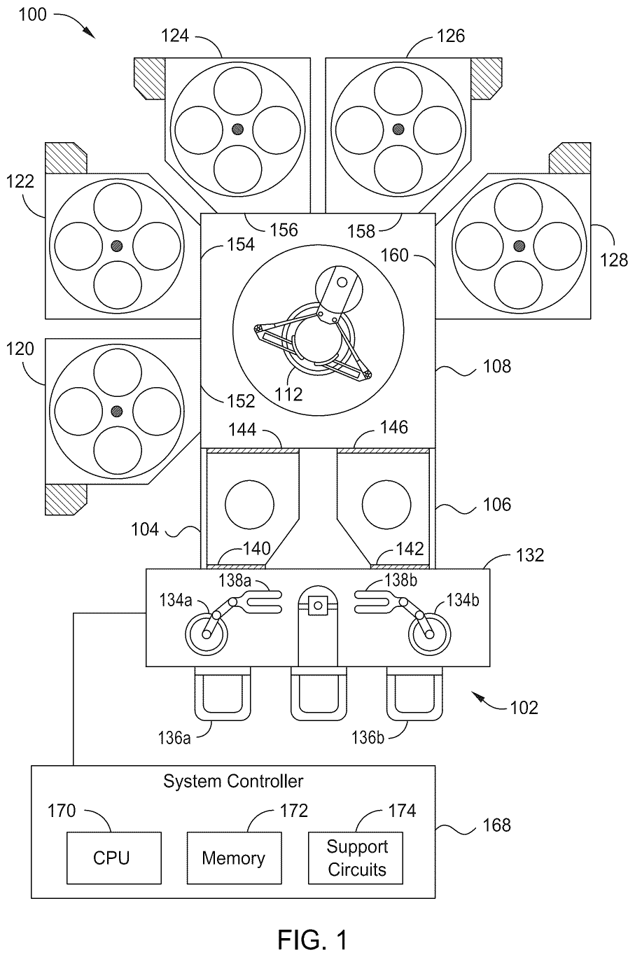

FIG. 1 illustrates a schematic top view of a multi-chamber substrate processing system 100 in accordance with one or more embodiments of the present disclosure. The substrate processing system 100 can be used for forming an interconnect structure coupled to an isolated metal gate structure in accordance with one or more embodiments of the present disclosure. The substrate processing system 100 generally includes a factory interface 102, load lock chambers 104, 106, transfer chambers 108, with respective transfer robot 112, and processing chambers 120, 122, 124, 126, and 128. As detailed herein, substrates in the substrate processing system 100 can be processed in and transferred between the various chambers without exposing the substrates to an ambient environment exterior to the substrate processing system 100, for example, an atmospheric ambient environment such as may be present in a fab. The substrates can be processed in and transferred between the various chambers maintained at a low chamber pressure, or a vacuum environment without breaking the low chamber pressure or vacuum environment among various processes performed on the substrates in the substrate processing system 100. Accordingly, the substrate processing system 100 may provide for an integrated solution for processing of substrates.

Alternate examples of processing systems that may be suitably modified in accordance with the teachings provided herein include the Endura®, Producer® or Centura® integrated processing systems or other suitable processing systems commercially available from Applied Materials, Inc., located in Santa Clara, California. It is contemplated that other processing systems (including those from other manufacturers) may be adapted to benefit from aspects described herein.

In the illustrated example of FIG. 1, the factory interface 102 includes a docking station 132 and factory interface robots 134a-b to facilitate transfer of substrates. The docking station 132 is adapted to accept one or more front opening unified pods (FOUPs) 136a-b. In some examples, each factory interface robot 134a-b generally includes a blade 138a-b disposed on one end of the respective factory interface robot 134a-b adapted to transfer the substrates from the factory interface 102 to the load lock chambers 104, 106.

The load lock chambers 104, 106 have respective ports 140, 142 coupled to the factory interface 102 and respective ports 144, 146 coupled to the transfer chamber 108. The transfer chamber 108 has respective ports 152, 154, 156, 158, and 160 coupled to processing chambers 120, 122, 124, 126, and 128. The ports 144, 146, 152, 154, 156, 158, and 160, can be, for example, slit valve openings with slit valves for passing substrates through by the transfer robot 112, and for providing a seal between respective chambers to prevent a gas from passing between the respective chambers. Generally, any port is open for transferring a substrate therethrough. Otherwise, the port is closed.

The load lock chambers 104, 106, the transfer chamber 108, and the processing chambers 120, 122, 124, 126, and 128, may be fluidly coupled to a gas and pressure control system (not specifically illustrated). The gas and pressure control system can include one or more gas pumps (for example, turbo pumps, cryo-pumps, roughing pumps) gas sources, various valves, and conduits fluidly coupled to the various chambers. In operation, the factory interface robot 134a-b transfers a substrate from the FOUP 136a-b through the port 140 or 142 to the load lock chamber 104 or 106. The gas and pressure control system then pumps down the load lock chamber 104 or 106. The gas and pressure control system further maintains the transfer chamber 108 with an interior low pressure or vacuum environment (which may include an inert gas). Hence, the pumping down of the load lock chamber 104 or 106 facilitates passing the substrate between, for example, the atmospheric environment of the factory interface 102 and the low pressure or vacuum environment of the transfer chamber 108.

With the substrate in the load lock chamber 104 or 106 that has been pumped down, the transfer robot 112 transfers the substrate from the load lock chamber 104 or 106 into the transfer chamber 108 through the port 144 or 146. The transfer robot 112 is then capable of transferring the substrate to and/or between any of the processing chambers 120, 122, 124, 126, and 128, through the respective ports 152, 154, 156, 158, and 160 for processing. The transfer and holding of the substrate within and among the various chambers can be in the low pressure or vacuum environment provided by the gas and pressure control system.

The processing chambers 120, 122, 124, 126, and 128 include multiple processing stations disposed within a common processing region. The processing chambers 120, 122, 124, 126, and 128, can be any appropriate chamber for processing a substrate. In some examples, the processing chamber 120 can be capable of performing an etch process, the processing chamber 122 can be capable of performing a cleaning process and plasma treatment process, and the processing chambers 126, and 128, can be capable of performing respective growth (e.g., deposition) processes. The processing chamber 120 may be a Selectra™ Etch chamber available from Applied Materials of Santa Clara, Calif. The processing chamber 122 may be a SiCoNi™ Pre-clean chamber available from Applied Materials of Santa Clara, Calif. The processing chamber 126, or 128, may be a Centura™ Epi chamber, Volta™ CVD/ALD chamber, or Encore™ PVD chambers available from Applied Materials of Santa Clara, Calif.

A system controller 168 is coupled to the substrate processing system 100 for controlling the substrate processing system 100 or components thereof. For example, the system controller 168 may control the operation of the substrate processing system 100 using a direct control of the processing chambers 104, 106, 108, 120, 122, 124, 126, and 128, of the substrate processing system 100 or by controlling controllers associated with the processing chambers 104, 106, 108, 120, 122, 124, 126, and 128. In operation, the system controller 168 enables data collection and feedback from the respective chambers to coordinate performance of the substrate processing system 100.

The system controller 168 generally includes a central processing unit (CPU) 170, memory 172, and support circuits 174. The CPU 170 may be one of any form of a general-purpose processor that can be used in an industrial setting. The memory 172, non-transitory computer-readable medium, or machine-readable storage device, is accessible by the CPU 170 and may be one or more of memory such as random access memory (RAM), read only memory (ROM), floppy disk, hard disk, or any other form of digital storage, local or remote. The support circuits 174 are coupled to the CPU 170 and may comprise cache, clock circuits, input/output subsystems, power supplies, and the like. The various methods disclosed herein may generally be implemented under the control of the CPU 170 by the CPU 170 executing computer instruction code stored in the memory 172 (or in memory of a particular processing chamber) as, for example, a software routine. That is, the computer program product is tangibly embodied on the memory 172 (or non-transitory computer-readable medium or machine-readable storage device). When the computer instruction code is executed by the CPU 170, the CPU 170 controls the chambers to perform processes in accordance with the various methods.

The instruction in memory 172 may be in the form of a program product, such as a program that implements the methods of the present disclosure. In one example, the disclosure may be implemented as a program product stored on a computer-readable storage media for use with a computer system. The program(s) of the program product define functions of the embodiments (including the methods described herein). Thus, the computer-readable storage media, when carrying computer-readable instructions that direct the functions of the methods described herein, are embodiments of the present disclosure. The system controller 168 is configured to perform methods such as the method 200 stored in the memory 172.

In particular embodiments, at least one of the processing chambers 120 and 122 is a pre-clean chamber configured to perform the pretreatment process of operation 220, at least one of the processing chambers is an etch chamber configured to perform the plasma treatment process of operation 230 of the method 200 without breaking vacuum between any of the operations 210-230.

In operation, a substrate having a feature formed therein may be transferred to a first processing chamber which is one of the processing chambers 120, 122, or 124 where the feature is exposed to a metal-halide pre-soak and a pretreatment process to remove, or clean, for example, native oxides formed on the feature. The substrate may then be transferred to a second processing chamber which is one of the processing chambers 124, 126, and 128, without breaking vacuum for additional processing (e.g., a metal-fill process, and/or an annealing process).

### Processing Sequence Example

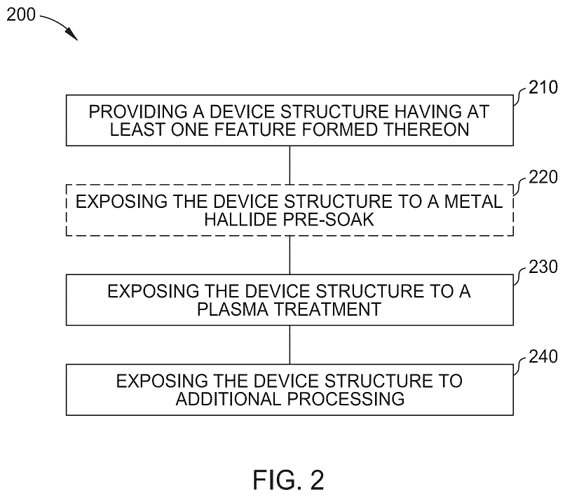

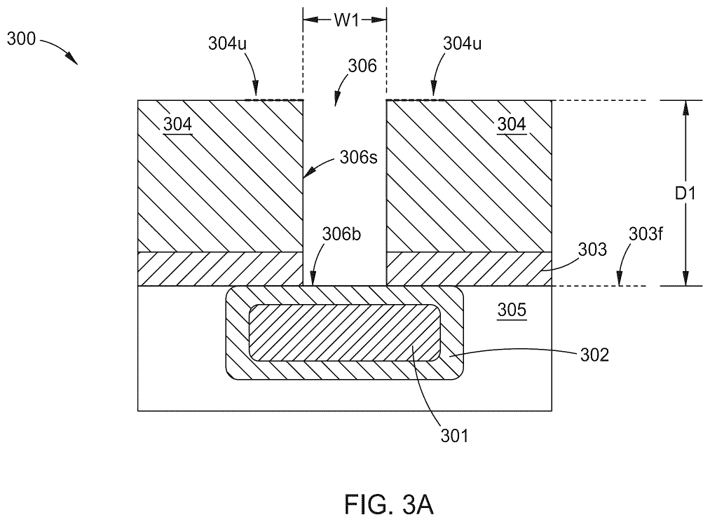

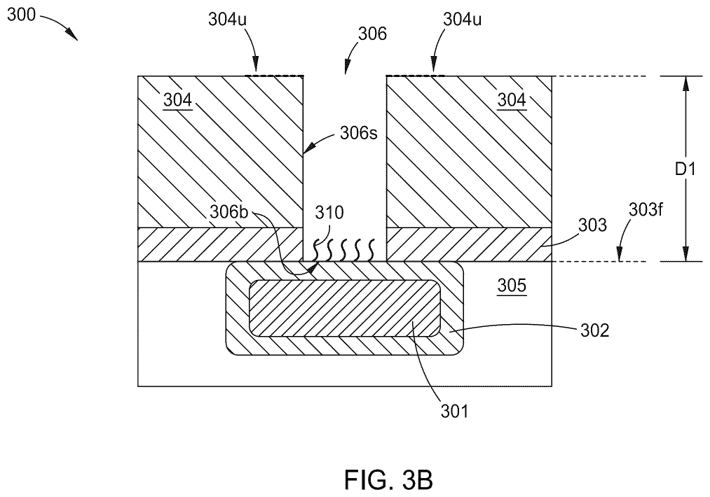

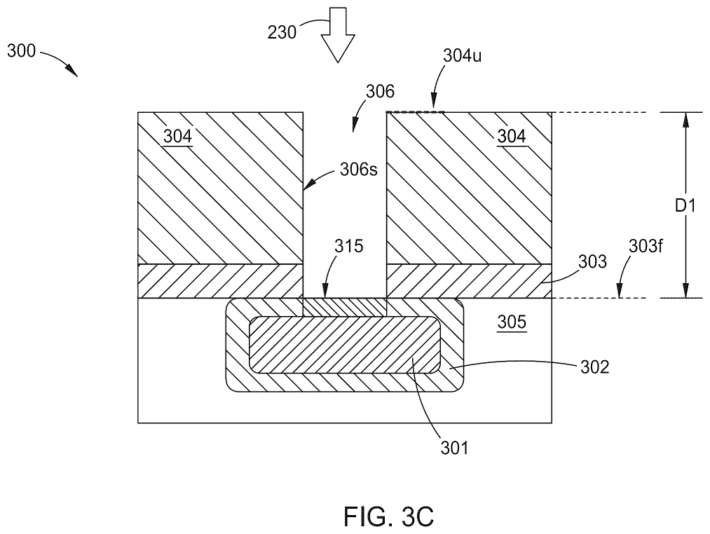

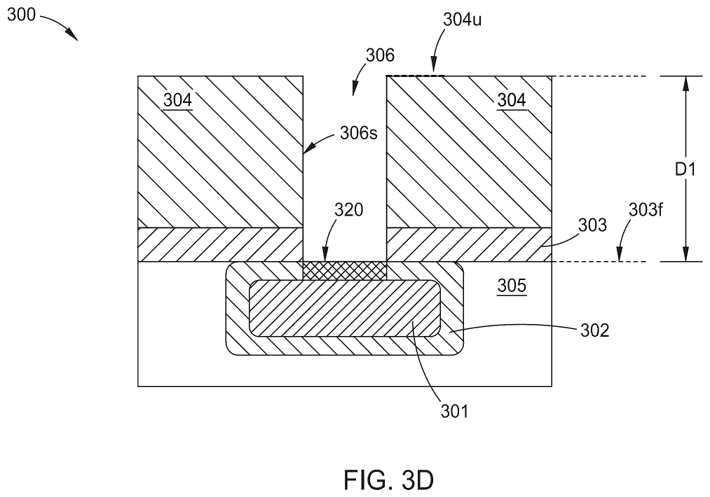

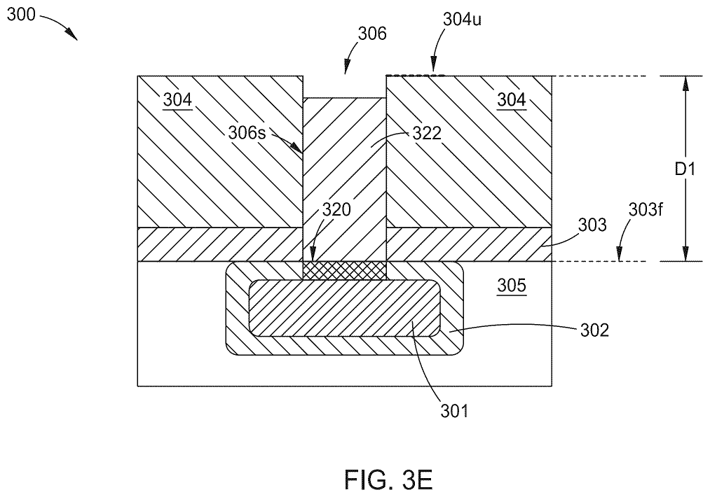

FIG. 2 illustrates a process flow diagram for a method of performing a metal halide pre-soak and a plasma treatment process sequence on a device structure in accordance with one or more embodiments described herein. FIGS. 3A-3E illustrate view of various stages of forming an interconnect structure coupled to an isolated metal gate of a field effect transistor, according to one or more embodiments of the present disclosure.

Although FIGS. 3A-3E are described in relation to the method 200, it will be appreciated that the structures disclosed in FIGS. 3A-3E are not limited to the method 200, but instead may stand alone as structures independent of the method 200. Similarly, although the method 200 is described in relation to FIGS. 3A-3E, it will be appreciated that the method 200 is not limited to the structures disclosed in FIGS. 3A-3D but instead may stand alone independent of the structures disclosed in FIGS. 3A-3E. It should be understood that FIGS. 3A-3E illustrate only partial schematic views of the formation of the interconnect structure coupled to an isolated metal gate, and the interconnect structure coupled to the isolated metal gate may contain any number of transistor, capacitor, or other useful sections and additional materials having aspects as illustrated in the figures. It should also be noted that although the method 200 illustrated in FIG. 2 is described sequentially, other process sequences that include one or more operations that have been omitted and/or added, and/or have been rearranged in another desirable order, fall within the scope of the embodiments of the disclosure provided herein.

At operation 210, as shown in FIG. 3A, a semiconductor device structure 300 having a feature 306 formed therein is provided. FIG. 3A illustrates a cross-sectional view of the semiconductor device structure 300 during intermediate stages of manufacturing corresponding to operation 210. The semiconductor device structure 300 includes an isolated metal gate 301, surrounded by a dielectric layer 302. In some examples, the dielectric layer 302 includes a dielectric material, such as the high-k dielectric material (HfOx), hafnium oxide. In one or more embodiments, the semiconductor device structure 300 includes additional multiple dielectric layers, such as dielectric layer 305, 303, and 304. The dielectric layer 303 is formed over a front side 303f of the isolated metal gate 301. The dielectric layer 304 is formed over the dielectric layer 303 and includes an upper surface 304u or field region.

In one or more embodiments, the additional multiple dielectric layers, such as dielectric layer 305, 303, and 304 include dielectric materials, such as a low-k dielectric (SiCOH), silicon oxide, silicon dioxide (SiO2), silicon nitride (Si3N4), silicon carbide (SiC), silicon oxynitride (SiON), aluminum oxide (Al2O3), aluminum nitride (AlN), a combination thereof, or multi-layers thereof. In some embodiments, the dielectric layer consists essentially of silicon oxide. It is noted that the foregoing descriptors, for example, silicon oxide, should not be interpreted to disclose any particular stoichiometric ratio. Accordingly, “silicon oxide” and the like will be understood by one skilled in the art as a material consisting essentially of silicon and oxygen without disclosing any specific stoichiometric ratio.

Still referring to FIG. 3A, the dielectric layer 304 is patterned to form the one or more feature(s) 306. The feature 306 may be a high aspect ratio (HAR) feature. In some embodiments, the feature 306 can be selected from a trench, a via, a hole, or a combination thereof. In particular embodiments, the feature is a trench. In other particular embodiments, the feature 306 is a via. In some embodiments, the feature 306 extends from an upper surface 304u of the dielectric layer 304 toward the frontside 303f of the isolated metal gate 301. The feature 306 includes sidewall surface(s) 306s and a bottom surface 306b extending between the sidewall surface(s) 306s. In some embodiments, the sidewall surface(s) 306s is tapered. The sidewall surface(s) 306s may be defined by one or more dielectric layers, such as the dielectric layer 304, 303 and the bottom surface 306b may be defined by the dielectric layer 302 (e.g., the high-k dielectric material (HfOx), hafnium oxide). In some embodiments, the sidewall surface(s) 306s may be defined by multiple dielectric layers, such as by dielectric layer 303 formed over a front side 303f of the isolated metal gate 301 and by dielectric layer 304 formed over the dielectric layer 303. The feature 306 has a first depth “D1” from the upper surface 304u to the bottom surface 306b and a width “W1” between the two sidewall surface(s) 306s. In some embodiments, the depth D1 is in a range of 2 nm to 200 nm. In some embodiments, the width W1 is in a range of 10 nm to 100 nm. In some embodiments, the feature 306 has an aspect ratio (D/W) in a range of 1 to 20.

Referring to FIG. 2, optionally, at operation 220, the semiconductor device structure 300 is exposed to a metal-halide pre-soak. FIG. 3B illustrates a cross-sectional view of the semiconductor device structure 300 during intermediate stages of manufacturing corresponding to operation 220. In some embodiments, the metal halide pre-soak process is performed in-situ in a processing chamber positioned on a cluster tool, for example, the substrate processing system 100 (see FIG. 1). During the metal halide pre-soak process the dielectric layer 302 defining the bottom surface 306b of the feature 306 of the semiconductor device structure 300 is exposed to a gas precursor (e.g., titanium tetrachloride (TiCl4)) from about 3 minutes to about 6 minutes at a temperature from about 200 degrees Celsius to about 500 degrees Celsius. The titanium tetrachloride (TiCl4) pre-soak process can cause the dielectric layer 302 (e.g., the high-k dielectric material (HfOx), hafnium oxide) defining the bottom surface 306b of the feature 306 of the semiconductor device structure 300 to be converted to a hafnium oxychloride (HfOCl2) layer 315 as shown in FIG. 3C.

During the conversion of the hafnium oxide (HfOx) dielectric layer 302 to a hafnium oxychloride (HfOCl2) layer 315, oxygen is released in the form of titanium oxychloride (TiOClO2), thus effectively reducing the resistivity of the metal gate contact. The H—Cl bond strength in the resulting hafnium oxychloride (HfOCl2) layer 315 during the metal halide pre-soak process of block 220 is about 516 kJ/mol. Therefore, the metal halide pre-soak of block 220 effectively improves conversion efficiency of the insulating HfOx dielectric layer 302 to a conducting layer, such as a hafnium nitride (HfN) layer, as will be discussed in during block 230, since the Hf-bond strength in HfN is about 534 kJ/mol.

Referring to FIG. 2, at operation 230, the semiconductor device structure 300 is exposed to a plasma treatment process. FIG. 3C illustrates a cross-sectional view of the semiconductor device structure 300 during intermediate stages of manufacturing corresponding to operation 230.

During operation 230, the hafnium oxychloride (HfOCl2) layer 315 resulting from the optional metal halide pre-soak process of block 220 is exposed to a plasma treatment process. In one or more embodiments, the plasma treatment process includes the use of precursor gases such as hydrogen-containing precursors that include atomic hydrogen (H), diatomic hydrogen (H2), ammonia (NH3), hydrocarbons (CxHy), incompletely halogen-substituted hydrocarbons, combinations thereof, or the like. In some embodiments, during the plasma treatment process, the hafnium oxychloride (HfOCl2) layer 315 shown in FIG. 3C is exposed to the precursor gas at a temperature suitable for thermal deposition, for example at a temperature of about 200 degrees Celsius to about 500 degrees Celsius and at a chamber pressure in a range from about 1 mT to about 2 mT. In some embodiments, the plasma treatment process can cause the converted hafnium oxychloride (HfOCl2) layer 315 and any remaining exposed portion of the hafnium oxide (HfOx) dielectric layer 302 to be converted to a conducting layer 320, such as a hafnium nitrogen oxide (HfNO) layer or a hafnium carbon oxide (HfCO) layer, as illustrated in FIG. 3D.

However, in some alternate embodiments of method 200, it may be desirable to not perform operation 220 prior to performing operation 230. In this configuration, the plasma treatment process can be performed directly on the hafnium oxide (HfOx) dielectric layer 302 to convert the exposed portion of the hafnium oxide (HfOx) dielectric layer 302 to a conducting layer 320, such as a hafnium nitrogen oxide (HfNO) layer or a hafnium carbon oxide (HfCO) layer, as shown in FIG. 3D.

FIG. 3D illustrates a cross-sectional view of the semiconductor device structure 300 during intermediate stages of manufacturing corresponding to operation 230. The process sequence example aforementioned resulting in the formation of conducting layer 320 (i.e., a hafnium nitrogen oxide (HfNO) layer or a hafnium carbon oxide (HfCO) layer) is improved by performing operations 220 and 230 of method 200. Stated otherwise, the optional metal halide pre-soak of block 220 followed by the plasma treatment process of block 230 improves the conversion efficiency of the non-conducting dielectric layer 302 to the conducting layer 320 by reducing the resistivity of the high-k dielectric layer 302 thus enabling in-situ metal fill during the additional processing of block 240.

Referring to FIG. 2, at operation 240, the semiconductor device structure 300 illustrated in FIG. 3D is exposed to additional processing. FIG. 3E illustrates a cross-sectional view of the semiconductor device structure 300 during intermediate stages of manufacturing corresponding to operation 240. In In one or more embodiments, additional processing may include a metal fill process.

Referring to FIG. 3E, at operation 240, the feature 306 is filled with a metal fill material 322. The metal fill material 322 may include tungsten (W), cobalt (Co), ruthenium (Ru), or molybdenum (Mo). The metal fill material may be formed of any suitable deposition process such as atomic ALD, CVD, physical vapor deposition (PVD), or a hybrid ALD/PVD process in a processing chamber such as the processing chamber 124, 126, or 128 shown in FIG. 1. After the metal fill process, the semiconductor device structure 300 may be planarized, by use of a chemical mechanical planarization process (CMP).

While the foregoing is directed to embodiments of the present disclosure, other and further embodiments of the disclosure may be devised without departing from the basic scope thereof, and the scope thereof is determined by the claims that follow.

What is claimed is:

1. A method of forming an interconnect within a device structure, comprising:
exposing the device structure to a metal halide pre-soak, wherein the device structure comprises at least one feature formed in a first dielectric layer, wherein the at least one feature exposes a surface of a second dielectric layer surrounding a metal gate;
exposing the device structure to a plasma treatment, and
at least partially filling the at least one feature with a metal fill material.

2. The method of claim 1, wherein the at least one feature is defined by sidewall surfaces formed in the first dielectric layer and the surface of the second dielectric layer extending between the sidewall surfaces.

3. The method of claim 2, wherein the second dielectric layer comprises a high-k dielectric material.

4. The method of claim 3, wherein the high-k dielectric material comprises hafnium oxide (HfO₂).

5. The method of claim 1, wherein the first dielectric layer comprises a low-k dielectric (SiCOH), silicon oxide, silicon dioxide (SiO₂), silicon nitride (Si₃N₄), silicon carbide (SiC), silicon oxynitride (SiON), aluminum oxide (Al₂O₃), aluminum nitride (AlN), a combination thereof, or multi-layers thereof.

6. The method of claim 1, wherein the metal halide pre-soak comprises exposing the device structure to titanium tetrachloride (TiCl₄) from about 3 minutes to about 6 minutes at a temperature from about 200 degrees Celsius to about 500 degrees Celsius.

7. The method of claim 1, wherein the plasma treatment comprises exposing the device structure to a plasma comprising hydrogen-containing precursors.

8. The method of claim 7, wherein the hydrogen-containing precursors comprise atomic hydrogen (H), diatomic hydrogen (H₂), ammonia (NH₃), hydrocarbons (CₓH_{y}), incompletely halogen-substituted hydrocarbons, or combinations thereof.

9. A method of forming an interconnect within a device structure, comprising:
exposing a first dielectric layer of a device structure to a plasma treatment process, wherein the device structure has at least one feature formed therein, wherein the at least one feature comprises:
a bottom surface and sidewalls;
the first dielectric layer disposed at the bottom surface, and
a second dielectric layer forming at least a portion of the sidewalls,
wherein the plasma treatment process comprises exposing the device structure to a plasma comprising hydrogen-containing precursors.

10. The method of claim 9, further comprising exposing the device structure to a metal halide pre-soak prior to exposing the first dielectric layer of the device structure to the plasma treatment process.

11. The method of claim 10, wherein the metal halide pre-soak comprises exposing the device structure to titanium tetrachloride (TiCl₄) from about 3 minutes to about 6 minutes at a temperature from about 200 degrees Celsius to about 500 degrees Celsius.

12. The method of claim 9, wherein the first dielectric layer comprises a low-k dielectric (SiCOH), silicon oxide, silicon dioxide (SiO₂), silicon nitride (Si₃N₄), silicon carbide (SiC), silicon oxynitride (SiON), aluminum oxide (Al₂O₃), aluminum nitride (AlN), a combination thereof, or multi-layers thereof.

13. The method of claim 9, wherein the second dielectric layer comprises a high-k dielectric material.

14. The method of claim 13, wherein the high-k dielectric material comprises hafnium oxide (HfO₂).

15. The method of claim 9, wherein the first dielectric layer and the second dielectric layer comprise different materials.

16. The method of claim 9, wherein the hydrogen-containing precursors comprise atomic hydrogen (H), diatomic hydrogen (H₂), ammonia (NH₃), hydrocarbons (CₓH_{y}), incompletely halogen-substituted hydrocarbons, or combinations thereof.

17. The method of claim 9, wherein the plasma treatment process is performed at a temperature of about 200 degrees about 200 degrees Celsius to about 500 degrees Celsius.

18. The method of claim 9, wherein the plasma treatment process is performed at a chamber pressure of about 1 mT to about 2 mT.

19. A method of forming an interconnect within a device structure, comprising:
exposing the device structure to a metal halide pre-soak, the metal halide pre-soak comprising exposing the device structure to titanium tetrachloride (TiCl₄) from about 3 minutes to about 6 minutes at a temperature from about 200 degrees Celsius to about 500 degrees Celsius, wherein the device structure comprises:
a bottom surface and sidewalls;
at least one feature formed in a first dielectric layer, wherein the at least one feature exposes a surface of a second dielectric layer surrounding a metal gate;
the first dielectric layer disposed at the bottom surface, wherein the first dielectric comprises hafnium oxide; and
the second dielectric layer forming at least a portion of the sidewalls; and
exposing the device structure to a plasma treatment process, the plasma treatment process comprising exposing the device structure to a plasma comprising hydrogen-containing precursors; and
at least partially filling the at least one feature with a metal fill material.

20. The method of claim 19, wherein the hydrogen-containing precursors comprise atomic hydrogen (H), diatomic hydrogen (H₂), ammonia (NH₃), hydrocarbons (CₓH_{y}), incompletely halogen-substituted hydrocarbons, or combinations thereof.
